(19) United States
(12) Patent Application Publication
(10) Pub. No.: US 2002/0121682 A1
(43) Pub. Date: Sep. 5, 2002

(54) STRAPLESS LEAD FRAME

(76) Inventors: RONALD B AZCARATE, BAGUIO CITY (PH); PRIMITIVO A PALASI, BAGUIO CITY (PH); PHILIP B SIMON, HOUSTON, TX (US)

Correspondence Address: TEXAS INSTRUMENTS INCORPORATED, P O BOX 655474, M/S 3999, DALLAS, TX, 75265

(21) Appl. No.: 09/392,899

(22) Filed: Sep. 9, 1999

Related U.S. Application Data
(60) Provisional application No. 60/099,595, filed on Sep. 9, 1998.

(51) Int. Cl. H01L 23/40; H01L 23/36; H01L 23/495

(52) U.S. Cl. 257/675; 257/666

(57) ABSTRACT

A lead frame that does not tie straps and a die bond pad is rectangular in shape, with the same number of lead frame leads (11) on opposite sides and a different number of lead frame lead frame leads (11) on adjacent sides. Lead frame leads (11) extend into the area in which the tie strap would normally be placed. A heat slug is (30) taped into the lead frame to provide a semiconductor die mount area. At least one lead (11) from one side of the lead frame, located where the tie strap is normally located, is connected via a bond wire (17a, 17b) to a bond pad (19) on the semiconductor die (18) on a side adjacent to the side where the lead frame lead is located.

### FIELD OF THE INVENTION

The invention relates to semiconductor devices, and more particularly to a lead frame, used with a heat slug, without tie straps providing for evenly distributive bond wires at the corners of the semiconductor die.

### BACKGROUND OF THE INVENTION

High pin count lead frames have closely spaced inner leads. Lead frames which have tie bars connecting the lead frame to the die pad tend to cause crowding of the lead frame leads and bond wires at the corners of the semiconductor die.

There are several technologies used to reduce the distance between the lead frame inner leads and the integrated circuit bonding pads. One of the most common technologies consists of attaching an interposer between the lead frame inner leads and the semiconductor chip. The interposer is usually made of the same material used in the fabrication of printed circuit boards. The interposer can be made of any material as long as it can be electrically isolated from the lead fingers and is compatible with the physical and mechanical characteristics of the integrated circuit chip and other packaging materials, including lead frames and die attach material. While these procedure tend to strengthen the lead frame leads, and or bond wires, it does not necessarily reduce crowding to the lead frame leads and bond wires connecting the semiconductor die at its corners.

### SUMMARY OF THE INVENTION

The invention is to a strapless lead frame and semiconductor package including a semiconductor die that is rectangular in shape, and a strapless lead frame with the same number of lead frame leads on opposite sides and a different number of lead frame leads on adjacent sides. Lead frame leads extend into the area in which the tie strap would normally be placed. A heat slug is taped to the lead frame to provide a semiconductor die mount area. At least one lead from one side of the lead frame, located where the tie strap is normally located, is connected via a bond wire to a bond pad on the semiconductor die on a side adjacent to the side where the lead frame lead is located.

The technical advance represented by the invention, as well as the objects thereof, will become apparent from the following description of a preferred embodiment of the invention when considered in conjunction with the accompanying drawings, and the novel features set forth in the appended claims.

### BRIEF DESCRIPTION OF THE DRAWINGS

FIG. 1 shows a prior art lead frame having tie straps connecting the corners of the die mount pad;

FIG. 1a shows a prior art lead frame with a rectangular die pad;

FIG. 2 is a partial view of the lead frame of FIG. 1;

FIG. 3 is a partial view of the lead frame of FIG. 1, the same as FIG. 2, with the tie strap removed;

FIG. 3a is an enlarged view of a portion of FIG. 3 showing the crowding of the bond wires;

FIG. 4 shows the redistribution of lead frame leads and bond wires in the area where the tie bar has been removed; and

FIG. 4a is an enlarged view of a portion of FIG. 4 showing the improvement of bond wire distribution according to the invention.

### DESCRIPTION OF A PREFERRED EMBODIMENT

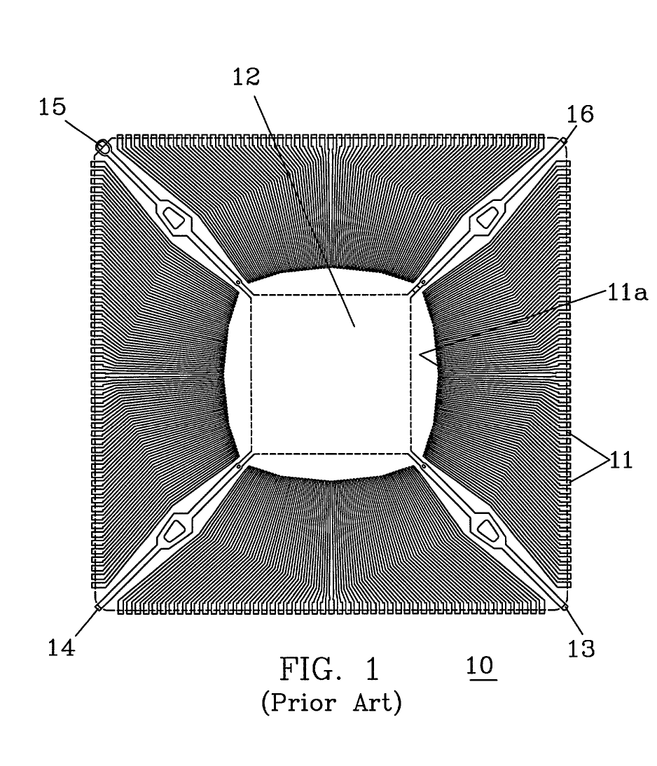

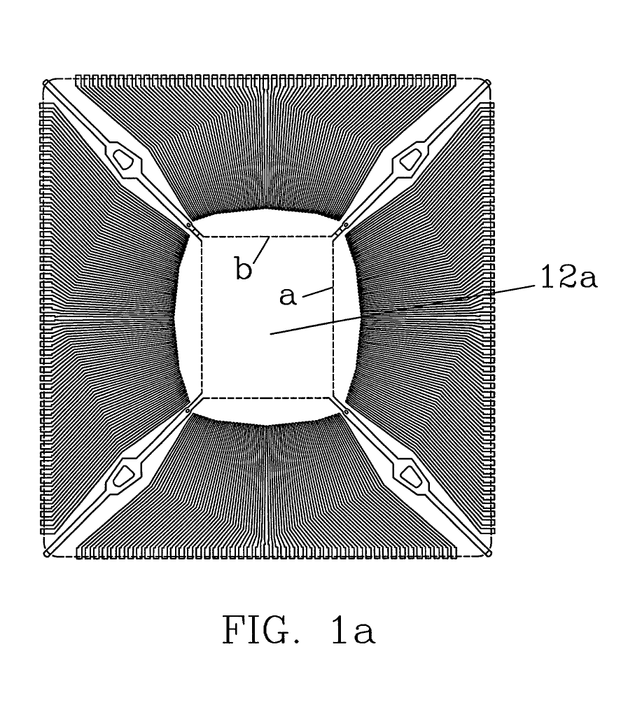

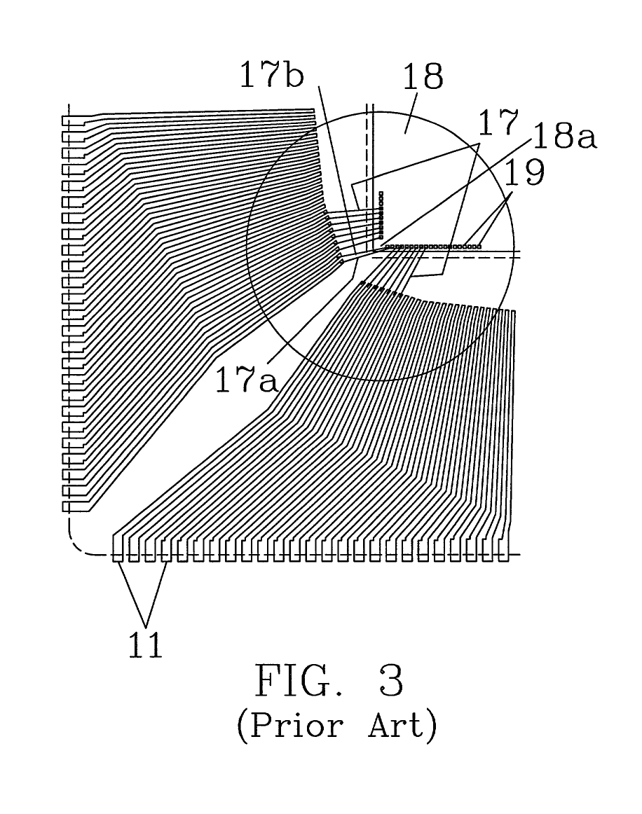

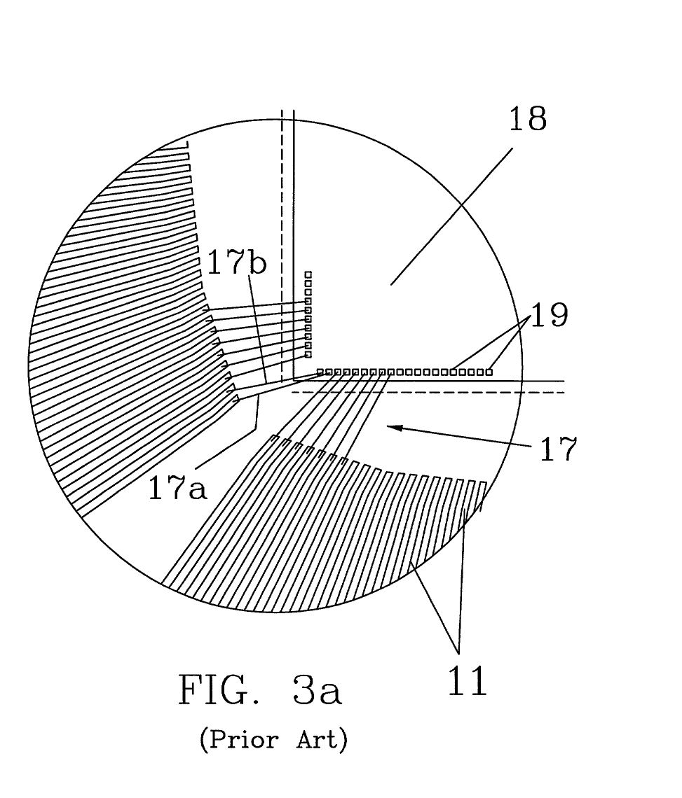

FIG. 1 is a prior art lead frame having a plurality of leads 11, a die mount pad 12 and four tie straps 13-16, which are attached to the die mount pad. Lead tips 11a are evenly spaced, but the combination of the corner of the semiconductor device and the bond pads thereon present lead routing problems as described below in FIGS. 3 and 3a.

The lead frame of FIG. 1a presents a greater problem in that the semiconductor die to be mounted in the lead frame is rectangular with a greater number of leads on, for example, side a than on smaller size side b.

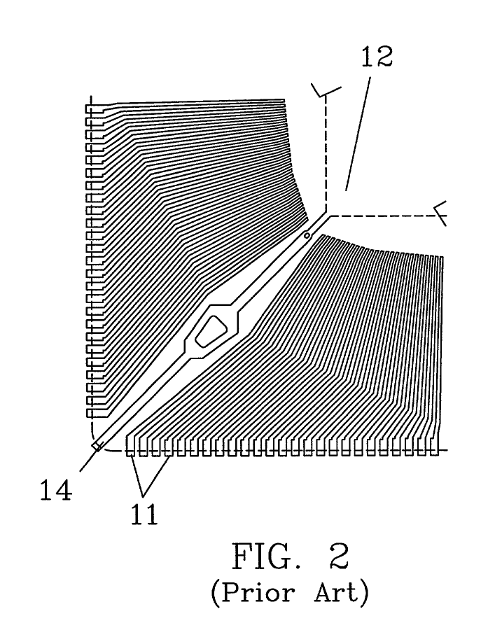

FIG. 2 is an enlarged partial view of the lead frame of FIG. 1, showing one tie strap 14 and leads 11. The leads 11 adjacent to tie strap 14 have to be bent around tie strap 14. This requires all the leads to be positioned in a smaller space because of the space required by tie strap 14.

FIG. 3 is the same view of lead frame of FIG. 2 with tie strap 14 removed. Semiconductor die 18 is shown with bond pads 19. Bond pads 19 are attached to lead frame leads 11 with bond wires 17. The bond wires 17 attached to bond pads 19 at positions removed from the semiconductor die corner 18a are fairly evenly spaced. However, the bond wires 17a and 17b are not adequately spaced, with a possible resulting short between the bond wires. This is especially true for the rectangular semiconductor die where bond wires from lead frame leads on one side of the lead frame are connected to bond pads on the adjacent side of the semiconductor die.

FIG. 3a is an enlarged partial view of FIG. 3 showing a portion of the leads 11, bond pads 19 on semiconductor die 18, and bond wires 17. The spacing in this enlarged view FIG. 3a shows the poor spacing between leads 17a and 17b as a result of the tie strap spacing.

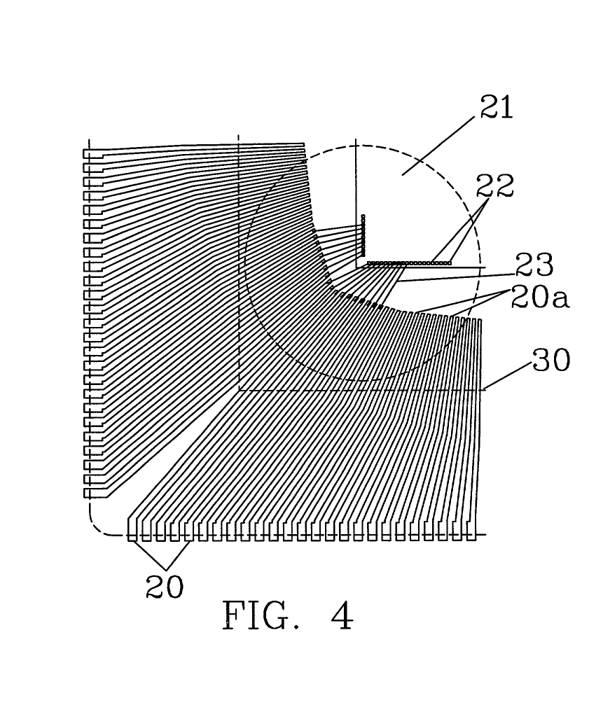

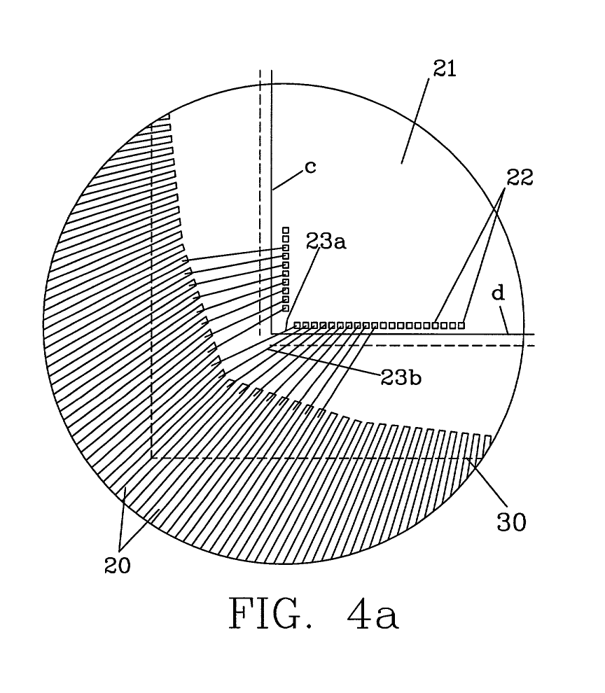

FIG. 4 shows a partial view of a lead frame with the tie strap removed, and the leads 20 positioned so that the ends 20a of leads 20 are evenly spaced around the corner of semiconductor die 21. Lead ends 20a are connected to bond pads 22 on semiconductor die 21. The spacing of bond wires 23 is evenly spaced as is the spacing between lead frame lead 20 and bond pads 22.

An advantage of the lead frame without a tie strap is that there is a tooling saving in that there is no need for tooling to cut the tie strap, and the resulting lead frame has a wider lead pitch at the corner of the semiconductor die and lead frame for high pin count packages.

FIG. 4a is an enlarged view of a portion of FIG. 4 clearly showing the improved spacing of the bond wires 23a and 23b. When compared with the spacing of bond wires 17a and 17b of FIG. 3 and FIG. 3a, the improvement of the lead frame leads spacing and the bond wire spacing of the lead frame without the tie strap is clearly seen. Bond wires 23a and 23b are from lead frame leads from one side of the lead frame that extend to bond pads on the adjacent side, or from lead frame leads that are in the space where the tie strap has been removed. As illustrated, leads 23a and 23b would be attached to bond pads on side of semiconductor die 21 if die 21 were square. However, since die 21 is rectangular, leads 23a and 23b extend to side d of die 21. If there were tie bars on the lead frame, this would not be possible since leads 23a and 23b would cross over the tie bar.

Since there are no tie bars to hold a die mount pad in place, in this embodiment, the semiconductor die is supported by a heat slug 30 which is taped under the lead frame. Heat slug 30 is taped to lead 20s and serves as both a heat sink and a die mount pad.

What is claimed:

1. A strapless lead frame/heat slug combination, comprising:
a plurality of lead frame leads distributed around a semiconductor die mount area, and extending into the area normally occupied by the lead frame strap; and
a heat slug attached under the lead frame with tape providing the die mount area.

2. The strapless lead frame according to claim 1, wherein the semiconductor die has four sides and the lead frame leads are evenly distributed on each of the four sides.

3. The strapless lead frame according to claim 1, wherein the lead frame has four sides and two of said four sides have a different number of leads from two other sides.

4. The strapless lead frame according to claim 1, where in said semiconductor die has a different number of bond pads on adjacent sides, and at least one of said bond pads is attached to a bond wire attached to a lead frame lead on a side of the lead frame adjacent to the side of the semiconductor die on with the bond pad is located.

5. A strapless lead frame for use with heat slug packages, comprising:
a plurality of lead frame leads distributed around a semiconductor die mount area, and extending into the area normally occupied by the lead frame strap;
a heat slug attached under the lead frame with tape providing a rectangular die mount area, there being the same number of lead frame leads on opposites sides of the lead frame and a different number of lead frame leads on adjacent sides of the lead frame.

6. The strapless lead frame according to claim 5, including a semiconductor die with a different number of bond pads on adjacent sides and the same number of bond pads on opposite sides, and at least one of said bond pads is attached to a bond wire attached to a lead frame lead on a side of the lead frame adjacent to the side of the semiconductor die on with the bond pad is located.
